(19) United States
(12) Patent Application Publication
(10) Pub. No.: US 2006/0289938 A1
(43) Pub. Date: Dec. 28, 2006

(54) Non-volatile memory devices and related methods

(76) Inventor: Hong-Soo Kim, Yongin-si (KR)

Correspondence Address: MYERS BIGEL SIBLEY & SAJOVEC, PO BOX 37428, RALEIGH, NC, 27627, US

(21) Appl. No.: 11/473,788

(22) Filed: Jun. 23, 2006

(30) Foreign Application Priority Data
Jun. 27, 2005 (KR) 2005-55910

(51) Int. Cl. H01L 29/76

(52) U.S. Cl. 257/365

(57) ABSTRACT

A semiconductor device may include a semiconductor substrate having an active region on a surface thereof. First, second, and third gate lines may cross the active region of the semiconductor substrate, and the first, second, and third gate lines may be arranged in parallel across the active region, and the second gate line may be between the first and third gate lines. A first insulating layer may fill a space between the first and second gate lines on the active region, and the first insulating layer may be a layer of a first insulating material. First insulating spacers may be provided on opposing sidewalls of the third gate line and on a sidewall of the second gate line adjacent to the third gate line, and the first insulating spacers may be spacers of the first insulating material. Second insulating spacers may be provided on sidewalls of the first insulating spacers so that the first insulating spacers are between the second insulating spacers and sidewalls of the second and third gate lines. Moreover, the second insulating spacers may be spacers of a second insulating material different than the first insulating material. Related methods are also discussed.

### RELATED APPLICATION

This application claims the benefit of priority from Korean Patent Application No. 2005-55910 filed on Jun. 27, 2005 in the Korean Intellectual Property Office (KIPO), the disclosure of which is hereby incorporated herein in its entirety by reference.

### FIELD OF THE INVENTION

The present invention relates in general to the field of semiconductor devices, and more particularly, to non-volatile memory devices and related methods.

### BACKGROUND

A cell string of a NAND-type non-volatile memory device may include a string selection line, a ground selection line and a plurality of parallel word lines. The string selection line and ground selection line may be disposed in parallel and may cross over an active region. Each of the word lines may be interposed between the string selection line and the ground selection line.

When a program operation is performed in a NAND-type non-volatile memory device, for example, 20V may be applied to the word lines of a programmed cell, 10V may be applied to the word lines of a non-programmed cell, a bias voltage Vcc (e.g., 1.5V) may be applied to the string selection line, and 0V may be applied to the ground selection line. When a programming operation of a word line adjacent to the ground selection line or the string selection line is performed, for example, a voltage difference between the ground selection line and the word line adjacent to the ground selection line or between the string selection line and the word line adjacent to the string selection line may be in the range of about 18.5 to about 20V. Thus, a voltage lower than 20 volts may result on the word line due to coupling between the selection line and the word line adjacent to the selection line, thereby causing a program error.

When an erase operation is performed in the NAND-type non-volatile memory device, 0V may be applied to all word lines, 20V may be applied to a semiconductor substrate, and a floating voltage may be applied to the ground selection line and the string selection line. Thus, a voltage higher than 0V may be generated on the word line adjacent to the selection line due to a coupling voltage induced from the floating voltage, thereby causing an erase error. These operation errors may cause degradation of dispersion of threshold voltages of cell transistors.

To reduce operation errors caused by the coupling effect between a selection line and a word line adjacent to the selection line and to reduce degraded dispersion of the threshold voltage, a gap between one selection line and one word line adjacent to the selection line may be wider than a gap between adjacent word lines. Increased gap widths, however, may reduce integration densities.

### SUMMARY

According to some embodiments of the present invention, a semiconductor device may include a semiconductor substrate including an active region on a surface thereof. First, second, and third gate lines may cross the active region of the semiconductor substrate. The first, second, and third gate lines may be arranged in parallel across the active region, and the second gate line may be between the first and third gate lines. A first insulating layer may fill a space between the first and second gate lines on the active region, and the first insulating layer may be a layer of a first insulating material. First insulating spacers may be on opposing sidewalls of the third gate line and on a sidewall of the second gate line adjacent to the third gate line, and the first insulating spacers may be insulating spacers of the first insulating material. Second insulating spacers may be provided on sidewalls of the first insulating spacers with the first insulating spacers being between the second insulating spacers and sidewalls of the second and third gate lines. Moreover, the second insulating spacers may be spacers of a second insulating material different than the first insulating material.

The first and second insulating materials may have different dielectric constants, and a dielectric constant of the first insulating material may be greater than a dielectric constant of the second insulating material. For example, the first insulating material may be a silicon nitride, and/or the second insulating material may be a silicon oxide, such as a medium temperature oxide (MTO).

The third gate line may be a selection line for a selection transistor, and the first and second gate lines may be first and second word lines for respective memory cell transistors. More particularly, the selection line may be a ground selection line or a string selection line for a NAND-type non-volatile memory device. A space between the first and second gate lines may be less than a space between the second and third gate lines, and a thickness of the first insulating spacers may be greater than half of a spacing between the first and second gate lines and less than half of a spacing between the second and third gate lines.

The semiconductor substrate may also include a second active region spaced apart from the first active region, and a peripheral gate pattern may be provided on the second active region. First peripheral insulating spacers of the first insulating material may be provided on opposite sidewalls of the peripheral gate pattern, and second peripheral insulating spacers of the second insulating material may be provided on sidewalls of the first peripheral insulating spacers. The first peripheral insulating spacers may thus be between the second peripheral insulating spacers and the sidewalls of the peripheral gate pattern. In addition, lightly doped source/drain regions of the second active region may be provided on opposite sides of the peripheral gate pattern, and a width of the lightly doped source/drain regions may be about equal to a combined thickness of the first and second peripheral insulating spacers. Moreover, highly doped source/drain regions of the second active region may be provided on opposite sides of the lightly doped source/drain regions.

Each of the first and second gate lines may include a gate insulating layer, a floating gate layer, a gate interlayer insulating layer, and a control gate electrode layer. Moreover, the gate insulating layer may be between the floating gate layer and the substrate, and the gate interlayer insulating layer may be between the floating gate layer and the control gate electrode layer. In addition or in an alternative, each of the first and second gate lines may include a tunnel insulating layer, a charge storage layer, a blocking insulating layer, and a gate conduction layer. Moreover, the tunnel insulating layer may be between the charge storage layer and the substrate, and the blocking insulating layer may be between the charge storage layer and the gate conduction layer.

According to some other embodiments of the present invention, a method of forming a non-volatile memory device may include forming an active region on a surface of a semiconductor substrate. A string selection line, a ground selection line, and a plurality of word lines may be arranged in parallel across the active region of the semiconductor substrate, and the plurality of word lines may be between the string selection line and the word selection line. First insulating layers may be formed filling spaces between adjacent word lines, and the first insulating layers may be layers of a first insulating material. First insulating spacers may be formed on sidewalls of the string and ground selection lines, on a sidewall of a first of the word lines adjacent to the string selection line, and on a sidewall of a last of the word lines adjacent to the ground selection line. Moreover, the first insulating spacers may be spacers of the first insulating material. After forming the first insulating layers and the first insulating spacers, second insulating spacers may be formed on sidewalls of the first insulating spacers, and the second insulating spacers may be spacers of a second insulating material different than the first insulating material.

The first and second insulating materials may have different dielectric constants, and a dielectric constant of the first insulating material may be greater than a dielectric constant of the second insulating material. For example, the first insulating material may be a silicon nitride, and/or the second insulating material may be a silicon oxide, such as a medium temperature oxide (MTO).

Forming the first insulating layers and forming the first insulating spacers may include forming a conformal layer of the first insulating material on the string selection line, on the ground selection line, on the plurality of word lines, and on the semiconductor substrate. The layer of the first insulating material may then be anisotropicly etched so that the first insulating layers of the first insulating material remain to fill the spaces between adjacent word lines and so that the first insulating spacers of the first insulating material remain.

Forming the second insulating spacers may include forming a conformal layer of the second insulating material on the first insulating spacers, on the first insulating layers, on the string and ground selection lines, on the plurality of word lines, and on the semiconductor substrate. The layer of the second insulating material may then be anisotropicly etched so that the second insulating spacers of the second insulating material remain.

A space between adjacent word lines may be less than a space between the first word line and the string selection line, and/or a space between adjacent word lines may be less than a space between the last word line and the ground selection line. A thickness of the first insulating spacers may be greater than half of a spacing between adjacent word lines, and the thickness of the first insulating spacers may be less than half of a spacing between first word line and the string selection line and/or less than half of a spacing between the last word line and the ground selection line.

Before forming the string and ground selection lines and the word lines, a second active region of the semiconductor substrate may be formed spaced apart from the first active region, and a peripheral gate pattern may be formed on the second active region. After forming the string and ground selection lines, the word lines, and the peripheral gate pattern, lightly doped source/drain regions may be formed on opposite sides of the string selection line, the ground selection line, the word lines, and the peripheral gate pattern, before forming the first insulating layers and before forming the first insulating spacers.

Forming the first and second insulating spacers may include forming first and second insulating spacers on sidewalls of the peripheral gate pattern. In addition, highly doped source/drain regions may be formed in the second active region on opposite sides of the peripheral gate pattern after forming the first and second insulating spacers.

According to still other embodiments of the present invention, a method of forming a semiconductor device may include forming first, second, and third gate lines arranged in parallel across an active region of a semiconductor substrate, with the second gate line being between the first and third gate lines. A first insulating layer may be formed to fill a space between the first and second gate lines on the active region, and the first insulating layer may be a layer of a first insulating material. First insulating spacers may be formed on opposing sidewalls of the third gate line and on a sidewall of the second gate line adjacent to the third gate line, and the first insulating spacers may include a the first insulating material. Second insulating spacers may be formed on sidewalls of the first insulating spacers with the first insulating spacers being between the second insulating spacers and sidewalls of the second and third gate lines. The second insulating spacers may be spacers of a second insulating material different than the first insulating material.

According to embodiments of the present invention, non-volatile memory devices and methods may be provided that reduce interference due to coupling.

According to other embodiments of the present invention, non-volatile memory devices and methods may be provided that can reduce interference caused due to coupling which may occur when a plurality of layers including an insulating layer with a low dielectric constant are interposed between gate lines. Programming errors and/or erase errors may thus be reduced.

According to embodiments of the present invention, a non-volatile memory device may include a first gate line and a second gate line adjacent to the first gate line. The first and second gate lines may be parallel with respect to each other and may respectively apply a different voltage. A first spacer may be configured to cover both lateral walls of each of the first and second gate lines. A second spacer may be configured to cover both lateral walls of the first spacer. The second spacer may be formed of material such as a Medium Temperature Oxide (hereafter, referred to MTO) having a dielectric constant lower than a silicon nitride.

According to other embodiments of the present invention, a non-volatile memory device may include a semiconductor substrate having a cell array area and a peripheral circuit area. Isolation layers may be formed on the semiconductor substrate to define an active region. A string selection line and a ground selection line may be substantially parallel with respect to each other and may cross over the active region. A plurality of word lines may be parallel with respect to each other between the string selection line and the ground selection line and may cross over the active region. A first insulating layer may fill a space between the word lines. A first spacer may cover one lateral wall of the word line adjacent to the string selection line, one lateral wall of the word line adjacent to the ground selection line and both lateral walls of the selection lines. A second spacer may cover lateral walls of the first spacer, and the first insulating layer may be formed of the same material as the first spacer.

The second spacer may be formed of material such as a MTO having a dielectric constant lower than that of a silicon nitride layer. A gap between adjacent word lines may be narrower than that between a string selection line and a word line adjacent to the string selection line, and narrower than that between a ground selection line and a word line adjacent to the ground selection line.

A thickness of the first spacer may be thicker than a half of a gap between the two neighboring word lines, but thinner than a half of a gap between the string selection line and the word line adjacent to the string selection line, and narrower than that between the ground selection line and the word line adjacent to the ground selection line.

According to still other embodiments of the present invention, a non-volatile memory device may include a peripheral gate pattern that is located in the peripheral circuit area. A lightly doped drain (LDD) region may be located in the semiconductor substrate on both lateral walls of the peripheral gate pattern. Source/drain regions may be located in the semiconductor substrate on both lateral walls of the LDD region.

The first and second spacers may sequentially cover both lateral walls of the gate pattern in the peripheral circuit, and a sum of the thicknesses of each of the first and second spacers may be equal to the width of the LDD region.

The word lines and the selection lines may respectively include a gate insulating layer, a floating gate, a gate interlayer insulating layer and a control gate which are sequentially stacked on a semiconductor substrate. The floating gate and the control gate in the word line may be separated by the gate interlayer insulating layer, while the control gates in the selection lines may be in contact with the floating gate via the interlayer insulating layer.

The word lines may respectively include a tunnel insulating layer, a charge storage layer, a blocking insulating layer, and a gate conducting layer, all of which are sequentially stacked on the semiconductor substrate. The selection lines may respectively include the tunnel insulating layer and the gate conducting layer, all of which are sequentially stacked on the semiconductor substrate.

According to other embodiments of the present invention, a method for forming a non-volatile memory device may include forming an isolation layer on a semiconductor substrate having a cell array region and a peripheral circuit region to define an active region. A string selection line and a ground selection line may be formed that are substantially parallel to each other and that cross over the active region in the cell array region. A plurality of parallel word lines may be interposed between the string selection line and the ground selection line. A first spacer layer may be conformally formed on the semiconductor substrate so as to fill spaces between the word lines. An anisotropic etch process may be performed wherein the etch is anisotropic with respect to the first spacer layer to form a first spacer covering both lateral walls of the selection line and a lateral wall of a word line adjacent to the selection line and to form a first spacer pattern filling spaces between the word lines. A second spacer layer may be conformally formed on the semiconductor substrate. A second spacer may be formed to cover lateral walls of the first spacer by performing the anisotropic etching process with respect to the second spacer layer.

The second spacer layer may be formed of a material such as an MTO having a dielectric constant lower than that of a silicon nitride layer. A gap between adjacent word lines may be narrower than that between the string selection line and a word line adjacent to the string selection line, and between the ground selection line and a word line adjacent to the ground selection line.

The first spacer may be thicker than a half of a gap between adjacent word lines, but thinner than a half of a gap between the string selection line and a word line adjacent to the string selection line, and between the ground selection line and a word line adjacent to the ground selection line.

According to embodiments of the present invention, a method for forming a non-volatile memory device may include forming a peripheral gate pattern on the peripheral circuit area before forming the first spacer layer. A lightly doped region may be formed in the active region of both sides of the word lines, the selection lines and the peripheral gate pattern, respectively. The first and second spacers may be formed to cover lateral walls of the peripheral gate pattern.

According to some embodiments of the present invention, a method for forming a non-volatile memory device may include forming a highly doped region in the semiconductor substrate at both sides of the second spacer in the peripheral circuit region, after forming the second spacer.

The second spacer may have a thickness that subtracts the thickness of the first spacer from the width of the LDD region (a lightly doped drain region of a peripheral circuit transistor) to improve a characteristic of the peripheral circuit formed of the peripheral gate pattern and impurity regions adjacent to the peripheral gate pattern.

### BRIEF DESCRIPTION OF THE DRAWINGS

Embodiments of the present invention will become more apparent by describing in detail examples of embodiments of the present invention with reference to the accompanying drawings, in which:

FIG. 1 is a plan view illustrating a NAND type non-volatile memory device according to embodiments of the present invention.

FIG. 2 is a cross-sectional view taken along section lines I-I′ and II-II′ of FIG. 1.

FIGS. 3 to 7 are cross-sectional views illustrating steps of forming the non-volatile memory device of FIG. 2 according to embodiments of the present invention.

FIG. 8 is a cross-sectional view taken along section lines I-I′ and II-II′ of FIG. 1 according to additional embodiments of the present invention.

FIG. 9 is a cross-sectional view taken along section lines I-I′ and II-II′ of FIG. 1 according to still additional embodiments of the present invention.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

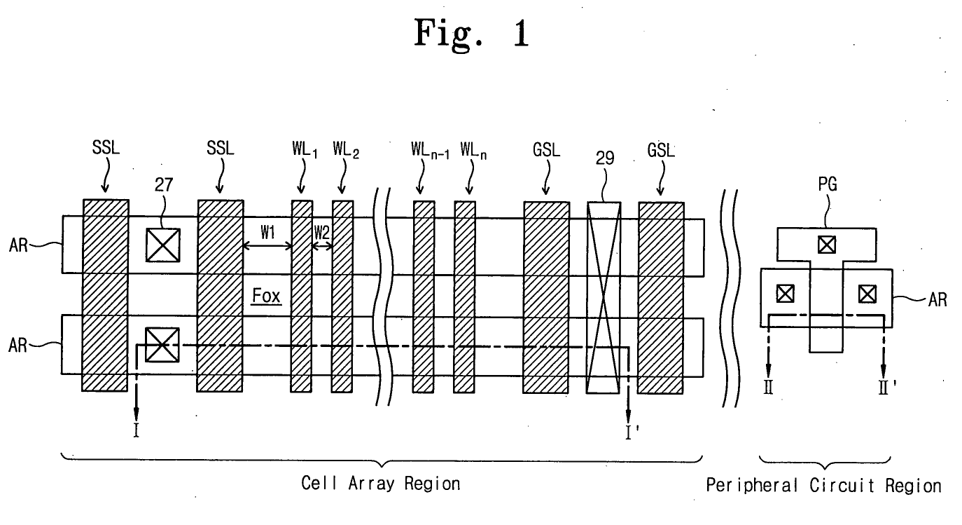

FIG. 1 is a plan view illustrating a NAND type non-volatile memory device according to embodiments of the present invention. Referring to FIG. 1, the non-volatile memory device may include a semiconductor substrate having a cell array region and a peripheral circuit region. An active region(s) on the semiconductor substrate may be defined by an isolation layer(s) (also referred to as a field oxide or FOX). The peripheral circuit region may enable a peripheral gate pattern to be located across and/or over the active region (AR). The cell array region may include a string selection line (SSL) and a ground selection line (GSL) which are parallel with respect to each other and cross over the active region(s) (AR). A plurality of word lines (WL₁, WL₂, . . . , WLₙ₋ₗ, WLₙ,) may be located between the selection lines (SSL, GSL). The string selection line (SSL), the ground selection line (GSL), and the word lines (WL₁, WL₂, . . . , WLₙ₋ₗ, WLₙ,) may provide one cell string. The cell string may be repeated symmetrically. A common source line 29 may be located between the ground selection line (GSL) and a neighboring ground selection line (GSL) and may cross over the active region (AR). A bit line contact 27 may be located on the active region between the string selection line (SSL) and a neighboring string selection line (SSL).

The n number of word lines (WL₁, WL₂, . . . , WLₙ₋₁, WLₙ) may include a first word line (WL₁) adjacent to the string selection line (SSL) and n^{th} word line (WL₁,) adjacent to the ground selection line (GSL). A first space (W1) between the string selection line (SSL) and the first word line (WL₁) and/or between the ground selection line (GSL) and the n^{th} word line (WLₙ) may be wider than a second space (W2) between adjacent word lines (WL₁, WL₂, . . . , WLₙ₋₁, WLₙ). Moreover, string and ground selection lines and the word lines may be referred to as gate lines herein.

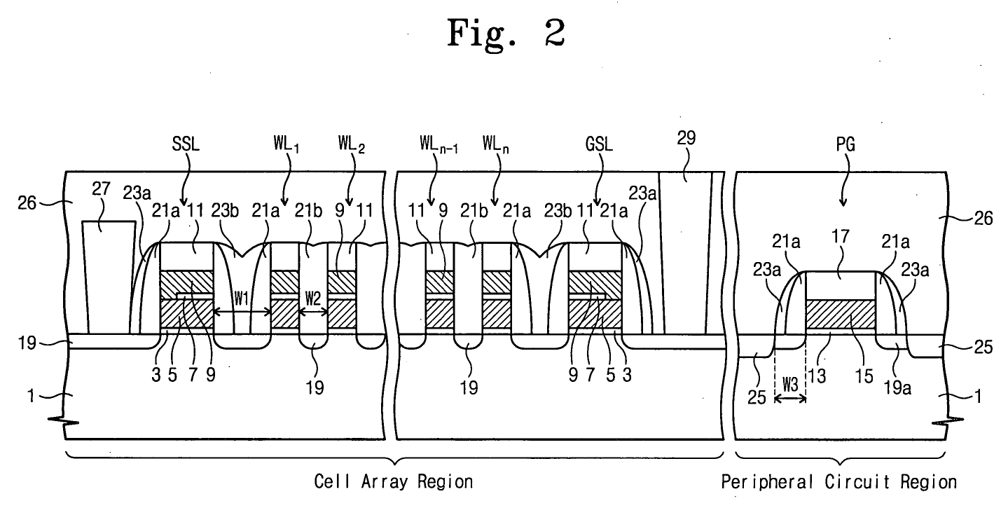

FIG. 2 is a cross-sectional view of a floating gate type non-volatile memory device according to embodiments of the present invention. In FIG. 2, a cross-sectional view of a cell array region is taken along the line I-I′ of FIG 1, and a cross-sectional view of a peripheral circuit region is taken along the line I-II′ of FIG. 1.

Referring to FIGS. 1 and 2, the selection lines (GSL, SSL) and the word lines (WL₁, WL₂, . . . , WLₙ₋₁, WLₙ) are located on a semiconductor substrate 1 in the cell array region. The lines (GSL, SSL, WL₁, WL₂, . . . , WLₙ₋₁, WLₙ) may each include a gate insulating layer 3, a floating gate 5, a gate interlayer insulating layer 7, a control gate 9 and a capping pattern 1, all of which are sequentially stacked on the semiconductor substrate 1. The gates 5 and 9 in the respective word lines (WL₁, WL₂, . . . , WLₙ₋₁, WLₙ,) are separated by the gate interlayer insulating layer 7, whereas the gates 5 and 9 in the selection lines (GSL, SSL) are in contact with each other because the width of the gate interlayer insulating layer 7 in the respective selection lines (GSL, SSL) is shorter than that of the respective gates 5 and 9. The gates 5 and 9 in the selection lines (SSL, GSL) may be configured so that portions thereof are in contact with each other. A peripheral gate pattern (PG) may be located in the peripheral circuit region. The peripheral circuit region may include a gate insulating layer 13, a gate electrode 15, and a capping pattern 17, which are sequentially stacked on the semiconductor substrate 1.

A first spacer(s) 21b may fill space(s) between word lines (WL₁, WL₂, . . . , WLₙ₋₁, WLₙ). A first spacer 21a may cover both lateral walls of the selection lines (GSL, SSL) and the peripheral gate pattern (PG), and one lateral wall of the first and n^{th} word lines adjacent to the selection lines (GSL, SSL). A second spacer pattern 23b may fill remaining space(s) between the first word line (WL₁) and the string selection line SSL and between the n^{th} word line (WL₁) and the ground selection line GSL. A second spacer 23amay cover lateral walls of the respective selection lines (GSL, SSL) that are located at outer portion(s) of the cell string, and lateral walls of the first spacer 21a that cover lateral walls of the peripheral gate pattern PG. Lightly doped regions 19 and 19a may be located in the semiconductor substrate 1 at both sides of the respective lines (GSL, SSL, WL₁, WL₂, . . . , WLₙ₋₁, WLₙ) and at both sides of the peripheral gate pattern PG. The lightly doped region 19a, which is located in the peripheral circuit region, may be referred to as a lightly doped drain (LDD) region. A highly doped region 25 may be located in the semiconductor substrate 1 adjacent to the second spacer 23a that covers lateral walls of the peripheral gate pattern PG. An interlayer insulating layer 26 may cover the lines (GSL, SSL, WL₁, WL₂, . . . , WLₙ₋₁, WLₙ) and the peripheral gate pattern PG. A bit line contact 27 and a common source line 29 may be located to be in contact with lightly doped regions 19 by penetrating the interlayer insulating layer 26 in the cell array region.

The first spacer pattern 21b and first spacer 21 a may be formed of the same material, such as a silicon nitride layer. The second spacer pattern 23b and the second spacer 23a may be formed of the same material, such as a material with a dielectric constant lower than that of a silicon nitride layer, for example, an MTO layer. The thickness of the first spacer 21a may be less than ½ the distance of the first space (W1) and greater than ½ the distance of the second space (W2). The second spacer 23a may have a thickness equal to a difference of a thickness of the first spacer 21a and a width (W3) of the LDD region to improve characteristics of the peripheral transistor formed of the peripheral gate pattern (PG) and the doped regions (19a, 25). Stated in other words, a width (W3) of the LDD region may be defined by the combined thicknesses of the spacers 21a and 23a.

In the non-volatile memory device, the first spacer 21a and the second spacer pattern 23b with a relatively low dielectric constant may be interposed between the first word line (WL₁) and the string selection line (SSL) and/or between the n^{th} word line (WLₙ) and the ground selection line (GSL), thereby potentially reducing interference. The lines (SSL, GSL, WL₁, WLₙ) may have relatively high differences between voltages which are applied thereto in a programming operation and/or in an erase operation. Accordingly, although the gap between the lines with high voltage difference may not be considerably wider, operation errors may be reduced.

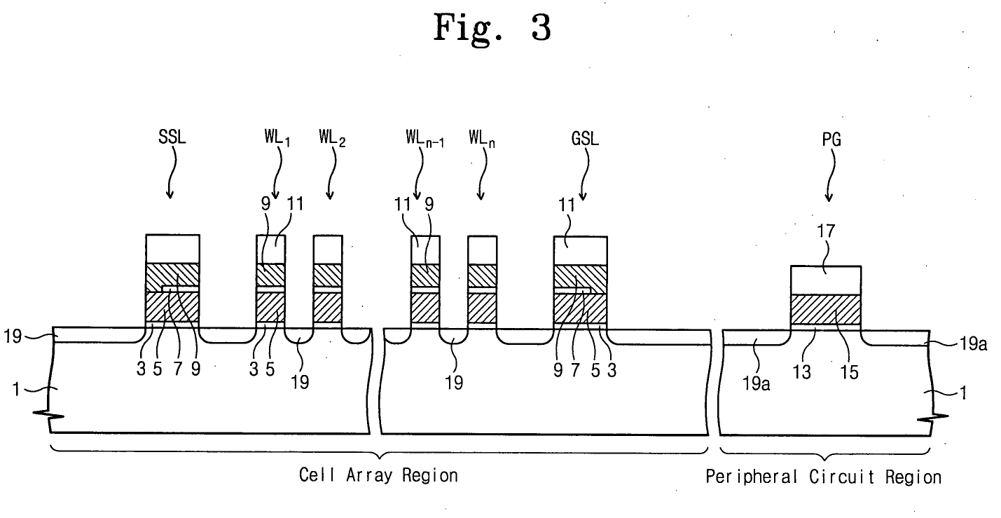

FIGS. 3 to 7 are cross-sectional views illustrating sequential steps of forming the non-volatile memory device of FIG. 2 according to some embodiments of the present invention.

Referring to FIG. 3, the respective lines (GSL, SSL, WL₁, WL₂, . . . , WLₙ₋₁, WLₙ) and the peripheral gate pattern PG may be formed on the semiconductor substrate 1 including a cell array region and a peripheral circuit region. The respective lines (GSL, SSL, WL₁, WL₂, . . . , WLₙ₋₁, WLₙ) and the peripheral gate pattern PG may be formed using various known methods, and explanation will thus be omitted. The lightly doped regions 19 and 19a may be formed (for example, using ion implantation) on the semiconductor substrate using the respective lines (GSL, SSL, WL₁, WL₂, . . . , WLₙ₋₁, WLₙ) and the peripheral gate pattern PG as an ion implantation mask. The lightly doped region 19 located in the cell array region and the lightly doped drain (i.e., LDD) region 19a located in the peripheral circuit region may be formed simultaneously. In some embodiments, the lightly doped region 19 and the lightly doped drain (i.e., LDD) region 19a may be formed before forming the lines (GSL, SSL, WL₁, WL₂, . . . , WLₙ₋₁, WLₙ) and before forming the peripheral gate pattern PG using another ion implantation mask, and/or the lightly doped region 19 and the lightly doped drain (i.e., LDD) region 19a may be formed using different impurities.

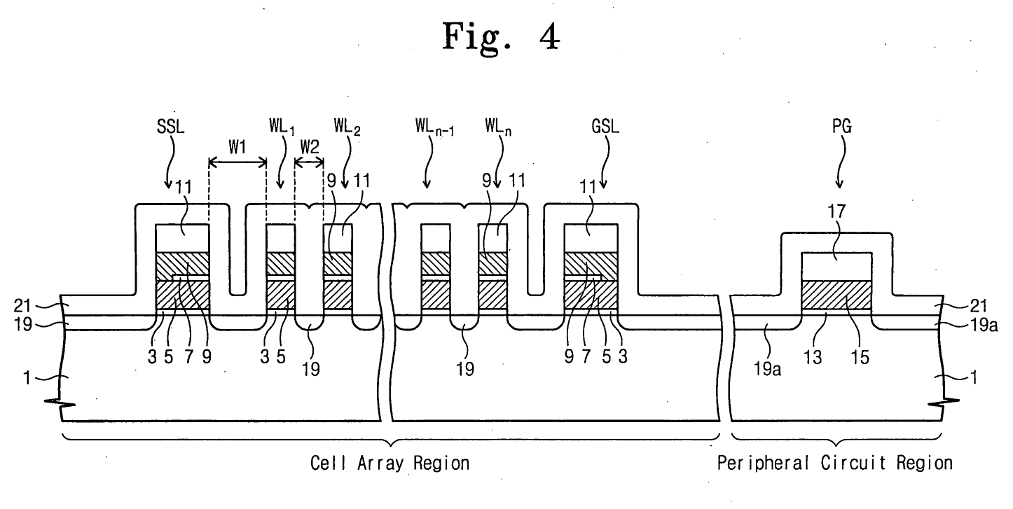

Referring to FIG. 4, a spacer layer 21 may be conformally formed on the semiconductor substrate 1 and on the respective lines (GSL, SSL, WL₁, WL₂, . . . , WLₙ₋₁, WLₙ) and on the peripheral gate pattern PG The first spacer layer 21 may be formed to be thinner than ½ the distance of the first space (W1) and thicker than ½ the distance of the second space (W2). Accordingly, the first spacer layer 21 may fill spaces between adjacent word lines (WL₁, WL₂, . . . , WLₙ₋₁).

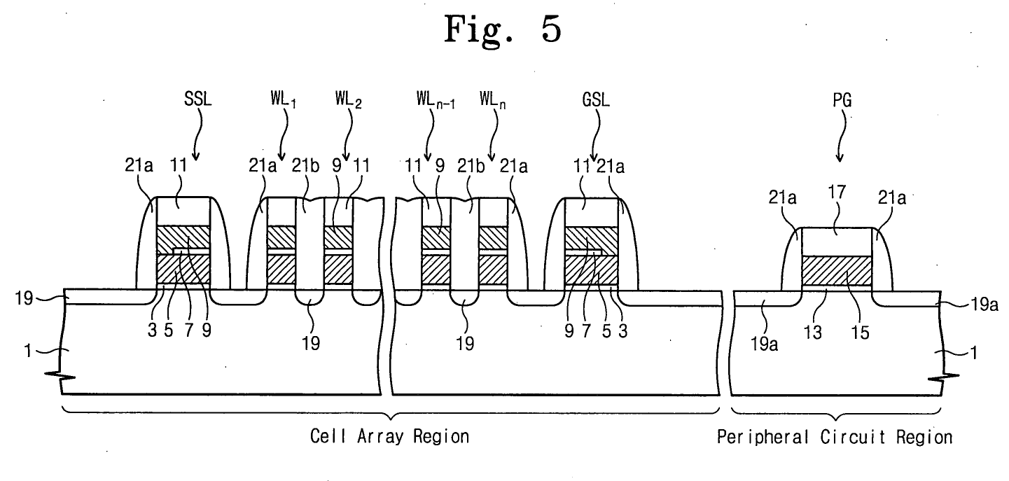

Referring to FIG. 5, as an anisotropic etching process of the first spacer layer 21 may be performed, the first spacer pattern(s) 21b fill spacers between the word lines (WL₁, WL₂, . . . , WLₙ₋₁), and so that the first spacer 21a covers both sidewalls of the selection lines (GSL, SSL) and the peripheral gate pattern (PG) and sidewalls of the first and n^{th} word lines adjacent to the selection lines (GSL, SSL). At this point, portions of the lightly doped region 19 between the string selection line (SSL) and the first word line (WL₁) and/or between the ground selection line (GSL) and the n^{th} word line (WLₙ) may be exposed.

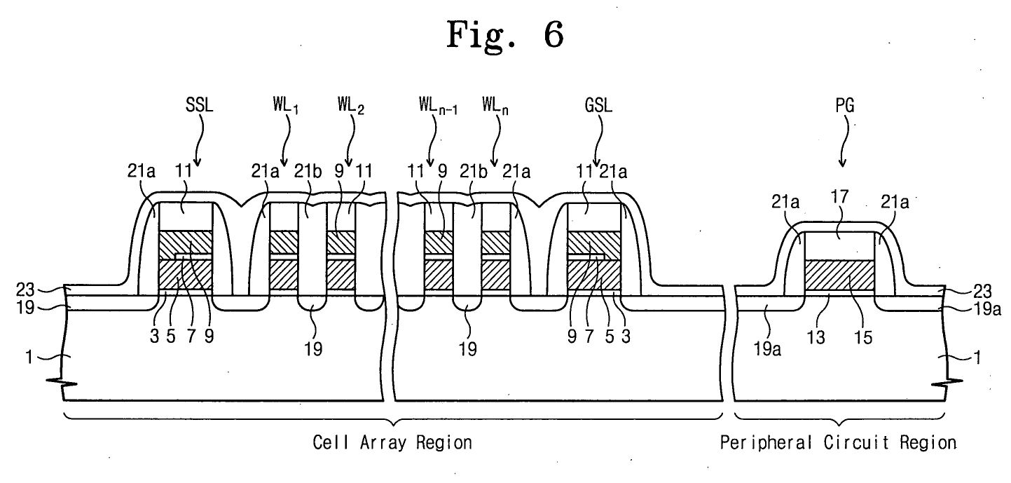

Referring to FIG. 6, a second spacer layer 23 may be conformally formed on the semiconductor substrate 1, on the spacers 21a-b, and on the lines GSL, SSL, PG, and WL₁₋ₙ. The second spacer layer 23 may be formed to have a thickness equal to a difference between a thickness of the first spacer 21a and a desired width (W3) of the LDD region to potentially improve characteristics of the peripheral transistor formed of the peripheral gate pattern (PG) and the doped regions (19a, 25). The second spacer layer 23 may fill or not fill space between the first word line (WL₁) and the string selection line (SSL) and/or between the n^{th} word line (WLₙ) and the ground selection line (GSL).

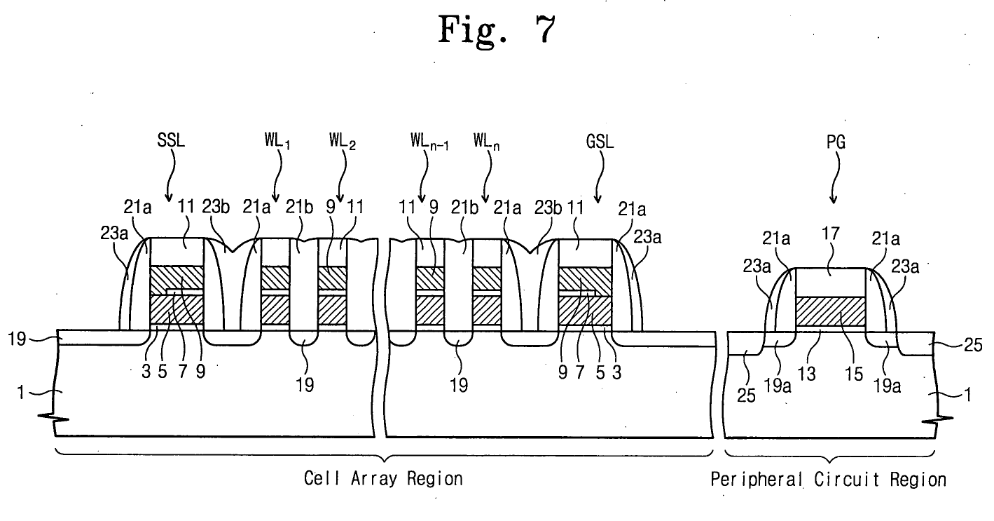

Referring to FIG. 7, second spacer patterns 23a and 23b may be formed by performing an anisotropic etching process on the second spacer layer 23. The second spacer pattern 23b may fill space between the first word line (WL₁) and the string selection line (SSL) and between the n^{th} word line (WLₙ) and the ground selection line (GSL). The spacer patterns 23a and 23b may be formed simultaneously. The second spacer 23amay cover outer lateral sidewalls of the respective selection lines (GSL, SSL), and lateral sidewalls of the first spacer 21a on lateral sidewalls of the peripheral gate pattern PG If each space between the first word line (WL₁) and the string selection line (SSL) and between the n^{th} word line (WLₙ) and the ground selection line (GSL) is wider, the second spacer pattern 23b may be omitted, and the second spacer 23a covering all lateral sidewalls of the first spacer 21a may be formed. A highly doped region 25 may be formed in the semiconductor substrate 1 using the first and second spacers 21a and 23a as an ion implantation mask in the peripheral circuit region, where the spacers cover the peripheral gate pattern (PG) and lateral sidewalls thereof.

Referring again to FIG. 2, an interlayer insulating layer 26 may be formed on the semiconductor substrate 1. A bit line contact 27 and a common source line 29 may be formed in contact with the lightly doped region 19 by penetrating the interlayer insulating layer 26 in the cell array region.

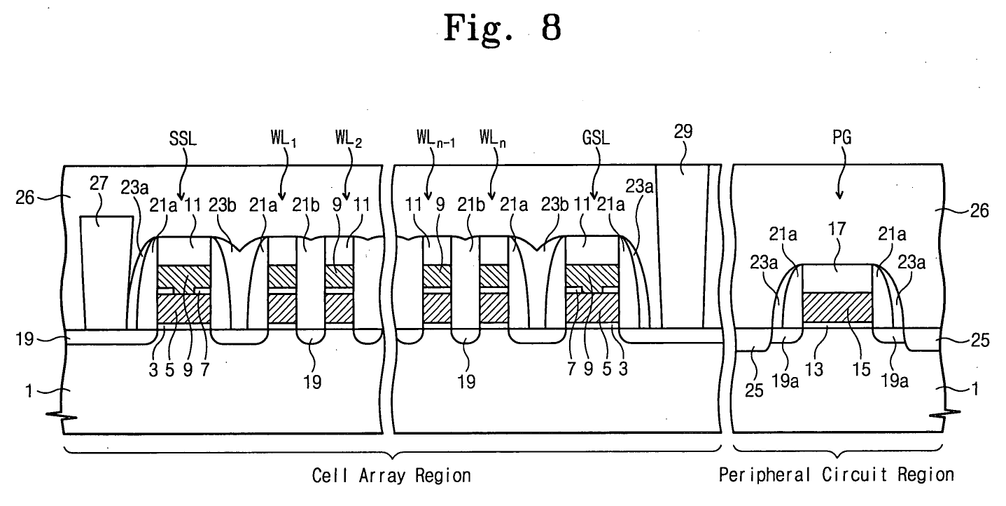

FIG. 8 is a cross-sectional view of a floating gate type non-volatile memory device according to other embodiments of the present invention. Referring to FIG. 8, sections of the selection lines (GSL, SSL) may be different from those of FIG. 2. The selection lines (GSL, SSL) may be formed to enable the gate interlayer insulating layer 7 to be in contact with both sides of the floating gate 5 and to join the central part of the floating gate 5 to that of the control gate 9. Other elements of FIG. 8 may be similar and/or identical with respect to those of FIG. 2.

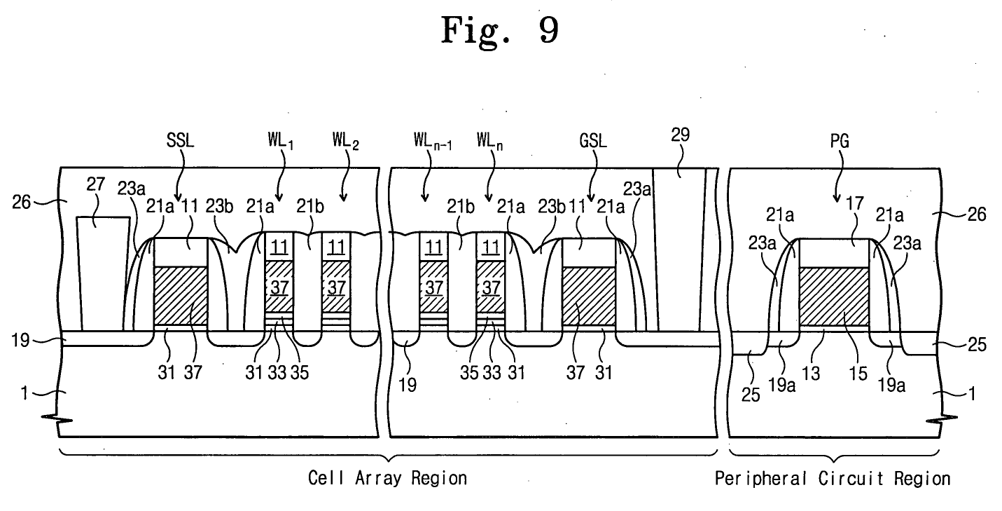

FIG. 9 is a cross-sectional view of a floating trap type non-volatile memory device according to still other embodiments of the present invention. Referring to FIG. 9, the word lines (WL₁, WL₂, . . . , WLₙ₋₁, WLₙ) may include a tunnel insulating layer 31, a charge storage layer 33, a blocking insulating layer 35 and a gate electrode 37 which are sequentially stacked on the semiconductor substrate 1. The selection lines (SSL, GSL) may include the tunnel insulating layer 31 and the gate electrode 37 which are sequentially stacked on the semiconductor substrate 1. Other elements of FIG. 9 may be identical to those of FIG. 2.

FIGS. 2, 8 and 9 are shown to demonstrate that embodiments of the present invention may be applied to the non-volatile memory devices having different structures.

As described above, non-volatile memory devices and methods for forming the same according to embodiments of the present invention may provide a plurality of layers (such as the insulating layer with a low dielectric constant) between adjacent lines having relatively high differences between voltages that are applied when the programming operation and the erase operation are performed. Interference due to coupling may thus be reduced. Although a gap between lines with the applied high voltage difference may not be wider, operation errors may be reduced and/or threshold voltage dispersion may be improved.

While the present invention has been particularly shown and described with reference to embodiments thereof, it will be understood by those of ordinary skill in the art that various changes in form and details may be made therein without departing from the spirit and scope of the present invention as defined by the following claims.

1. A semiconductor device comprising:
a semiconductor substrate including an active region on a surface thereof;
first, second, and third gate lines crossing the active region of the semiconductor substrate, wherein the first, second, and third gate lines are arranged in parallel across the active region, and wherein the second gate line is between the first and third gate lines;
a first insulating layer filling a space between the first and second gate lines on the active region wherein the first insulating layer comprises a first insulating material;
first insulating spacers on opposing sidewalls of the third gate line and on a sidewall of the second gate line adjacent to the third gate line wherein the first insulating spacers comprise the first insulating material; and
second insulating spacers on sidewalls of the first insulating spacers wherein the first insulating spacers are between the second insulating spacers and sidewalls of the second and third gate lines, wherein the second insulating spacers comprise a second insulating material different than the first insulating material.

2. A semiconductor device according to claim 1 wherein the first and second insulating materials have different dielectric constants.

3. A semiconductor device according to claim 2 wherein a dielectric constant of the first insulating material is greater than a dielectric constant of the second insulating material.

4. A semiconductor device according to claim 1 wherein the first insulating material is a silicon nitride.

5. A semiconductor device according to claim 1 wherein the second insulating material is a silicon oxide.

6. A semiconductor device according to claim 5 wherein the silicon oxide is a medium temperature oxide (MTO).

7. A semiconductor device according to claim 1 wherein the third gate line comprises a selection line for a selection transistor, wherein the first and second gate lines comprise first and second word lines for respective memory cell transistors.

8. A semiconductor device according to claim 7 wherein the selection line comprises one of a ground selection line or a string selection line.

9. A semiconductor device according to claim 1 wherein a space between the first and second gate lines is less than a space between the second and third gate lines.

10. A semiconductor device according to claim 9 wherein a thickness of the first insulating spacers is greater than half of a spacing between the first and second gate lines and less than half of a spacing between the second and third gate lines.

11. A semiconductor device according to claim 1 wherein the semiconductor substrate includes a second active region spaced apart from the first active region, the semiconductor device further comprising:
a peripheral gate pattern on the second active region;
first peripheral insulating spacers comprising the first insulating material on opposite sidewalls of the peripheral gate pattern;
second peripheral insulating spacers comprising the second insulating material on sidewalls of the first peripheral insulating spacers so that the first peripheral insulating spacers are between the second peripheral insulating spacers and the sidewalls of the peripheral gate pattern;
lightly doped source/drain regions of the second active region on opposite sides of the peripheral gate pattern wherein a width of the lightly doped source/drain regions is about equal to a combined thickness of the first and second peripheral insulating spacers; and
highly doped source/drain regions of the second active region on opposite sides of the lightly doped source/drain regions.

12. A semiconductor device according to claim 1 wherein each of the first and second gate lines comprises a gate insulating layer, a floating gate layer, a gate interlayer insulating layer, and a control gate electrode layer, wherein the gate insulating layer is between the floating gate layer and the substrate, and wherein the gate interlayer insulating layer is between the floating gate layer and the control gate electrode layer.

13. A semiconductor device according to claim 1 wherein each of the first and second gate lines comprises a tunnel insulating layer, a charge storage layer, a blocking insulating layer and a gate conduction layer, wherein the tunnel insulating layer is between the charge storage layer and the substrate, and wherein the blocking insulating layer is between the charge storage layer and the and the gate conduction layer.

14. A semiconductor device according to claim 1 wherein the second insulating spacers between the second and third gate lines fill a space between the first insulating spacers between the second and third gate lines.

15. A method of forming a non-volatile memory device, the method comprising:
forming an active region on a surface of a semiconductor substrate;
forming a string selection line, a ground selection line, and a plurality of word lines arranged in parallel across the active region of the semiconductor substrate, wherein the plurality of word lines are between the string selection line and the word selection line;
forming first insulating layers filling spaces between adjacent word lines wherein the first insulating layers comprise a first insulating material;
forming first insulating spacers on sidewalls of the string and ground selection lines, on a sidewall of a first of the word lines adjacent to the string selection line, and on a sidewall of a last of the word lines adjacent to the ground selection line, wherein the first insulating spacers comprise the first insulating material; and
after forming the first insulating layers and the first insulating spacers, forming second insulating spacers on sidewalls of the first insulating spacers wherein the second insulating spacers comprise a second insulating material different than the first insulating material.

16. A method according to claim 15 wherein the first and second insulating materials have different dielectric constants.

17. A method according to claim 16 wherein a dielectric constant of the first insulating material is greater than a dielectric constant of the second insulating material.

18. A method according to claim 15 wherein the first insulating material is a silicon nitride.

19. A method according to claim 15 wherein the second insulating material is a silicon oxide.

20. A method according to claim 19 wherein the silicon oxide is a medium temperature oxide (MTO).

21. A method according to claim 15 wherein forming the first insulating layers and forming the first insulating spacers comprise: forming a conformal layer of the first insulating material on the string selection line, on the ground selection line, on the plurality of word lines, and on the semiconductor substrate; and
anisotropicly etching the layer of the first insulating material so that the first insulating layers of the first insulating material remain to fill the spaces between adjacent word lines and so that the first insulating spacers of the first insulating material remain.

22. A method according to claim 15 wherein forming the second insulating spacers comprises:
forming a conformal layer of the second insulating material on the first insulating spacers, on the first insulating layers, on the string and ground selection lines, on the plurality of word lines, and on the semiconductor substrate; and
anisotropicly etching the layer of the second insulating material so that the second insulating spacers of the second insulating material remain.

23. A method according to claim 15 wherein a space between adjacent word lines is less than a space between the first word line and the string selection line, and/or wherein a space between adjacent word lines is less than a space between the last word line and the ground selection line.

24. A method according to claim 15 wherein a thickness of the first insulating spacers is greater than half of a spacing between adjacent word lines, and wherein the thickness of the first insulating spacers is less than half of a spacing between first word line and the string selection line and/or less than half of a spacing between the last word line and the ground selection line.

25. A method according to claim 15 further comprising:
before forming the string and ground selection lines and the word lines, forming a second active region of the semiconductor substrate spaced apart from the first active region;
forming a peripheral gate pattern on the second active region;
after forming the string and ground selection lines, the word lines, and the peripheral gate pattern, forming lightly doped source/drain regions on opposite sides of the string selection line, the ground selection line, the word lines, and the peripheral gate pattern, before forming the first insulating layers and before forming the first insulating spacers.

26. A method according to claim 25 wherein forming the first and second insulating spacers comprises forming first and second insulating spacers on sidewalls of the peripheral gate pattern.

27. A method according to claim 26 further comprising:
after forming the first and second insulating spacers, forming highly doped source/drain regions in the second active region on opposite sides of the peripheral gate pattern.

28. A method according to claim 15 wherein the second insulating spacers between the first word line and the string selection line and between the last word line and the ground selection line fill a space between the first insulating spacers between the first word line and the string selection line and between the last word line and the ground selection line.

29. A method of forming a semiconductor device, the method comprising:
forming first, second, and third gate lines arranged in parallel across an active region of a semiconductor substrate, wherein the second gate line is between the first and third gate lines;
forming a first insulating layer filling a space between the first and second gate lines on the active region wherein the first insulating layer comprises a first insulating material;
forming first insulating spacers on opposing sidewalls of the third gate line and on a sidewall of the second gate line adjacent to the third gate line wherein the first insulating spacers comprise a the first insulating material; and
forming second insulating spacers on sidewalls of the first insulating spacers wherein the first insulating spacers are between the second insulating spacers and sidewalls of the second and third gate lines, wherein the second insulating spacers comprise a second insulating material different than the first insulating material.
